(19) United States
(12) Patent Application Publication
(10) Pub. No.: US 2026/0136748 A1
(43) Pub. Date: May 14, 2026

(54) BIODEGRADABLE MEMRISTOR AND METHOD OF MANUFACTURING THE SAME

(71) Applicants: POSCO Holdings Inc., Pohang-si (KR); RESEARCH INSTITUTE OF INDUSTRIAL SCIENCE & TECHNOLOGY, Pohang-si (KR); POSTECH Research and Business Development Foundation, Pohang-si (KR)

(72) Inventors: Junsuk RHO, Pohang-si (KR); Jaebum NOH, Pohang-si (KR); Jehyeon SHIN, Pohang-si (KR)

(73) Assignees: POSCO Holdings Inc., Pohang-si (KR); RESEARCH INSTITUTE OF INDUSTRIAL SCIENCE & TECHNOLOGY, Pohang-si (KR); POSTECH Research and Business Development Foundation, Pohang-si (KR)

(21) Appl. No.: 19/386,452

(22) Filed: Nov. 12, 2025

(30) Foreign Application Priority Data
Nov. 13, 2024 (KR) 10-2024-0161466

(51) Int. Cl. H10K 10/50; H10K 10/82; H10K 85/00

(52) U.S. Cl. CPC H10K 10/50; H10K 10/82; H10K 85/761

(57) ABSTRACT

Provided is a biodegradable memristor including: a substrate; a lower electrode formed on the substrate; a solid polymer electrolyte (SPE) layer formed on the lower electrode; and a magnesium electrode formed on the SPE layer.

### CROSS-REFERENCE TO RELATED APPLICATION

This application claims the benefit of Korean Patent Application No. 10-2024-0161466, filed on Nov. 13, 2024 in the Korean Intellectual Property Office, the disclosure of which is incorporated herein by reference.

### BACKGROUND

### 1. Field

The present invention relates to a biodegradable memristor and a method of manufacturing the same.

### 2. Description of the Related Art

A memristor is a neoelectronic device with electrically variable resistance, specifically a semiconductor device of which internal electrical characteristics change according to variations in voltage or current. A physically transient electronic device (PiTED) refers to an electronic device having a characteristic of selectively exhibiting a physically transient function depending on the environment. This technology represents an innovative approach to reducing the environmental burden of conventional electronic devices, and provides a solution for reducing electronic waste by replacing existing electronic devices with dissolvable PiTED memristors.

Conventionally, there have been efforts to develop memristors that are biodegradable and have a flexible structure. However, even when biodegradable materials are used, it is difficult to develop a memristor that implements biodegradability together with compatibility with physiological environments of the human body while achieving a level of data-retention capability sufficient to operate as an electronic device.

### SUMMARY

Therefore, it is an aspect of the present invention to provide a biomemristor that is mechanically flexible and has excellent biocompatibility and biodegradability, thereby being usable as a bio-electronic device in various fields, and a method of manufacturing the same.

The technical objectives of the present invention are not limited to the above, and other objectives may become apparent to those of ordinary skill in the art based on the following description.

According to an embodiment of the present invention, there is provided a biodegradable memristor including: a substrate; a lower electrode formed on the substrate; a solid polymer electrolyte (SPE) layer formed on the lower electrode; and a magnesium electrode formed on the SPE layer.

The biodegradable memristor may further include a conductive filament formed within the SPE layer through application of an external bias.

The biodegradable memristor may have physically transient capability.

The physically transient capability may include forming a conductive filament within the SPE layer through application of an external bias, and selectively disconnecting the conductive filament by an external environment.

The disconnecting of the conductive filaments may be performed through a method including one or more of application of a reverse polarity voltage, decomposition of the magnesium electrode, hydrolysis of the conductive filament, and hydrolysis of the SPE layer.

The SPE layer may include collagen.

The SPE layer may include collagen, and further include one or more of gelatin, silk fibroin, enzyme, sericin, lysozyme, amylose, amylopectin, and albumen.

The SPE layer may further include conductive particles.

The conductive particles may include one or more selected from metals, metal oxides, metal nitrides, conductive polymers, and quantum dots.

The substrate may include one or more of glass, silicon, poly(ethylene terephthalate) (PET), poly(ethylene naphthalate) (PEN), polyethersulfone (PES), polystyrene (PS), polycarbonate (PC), polyimide (PI), polydimethylsiloxane (PDMS), and polyacrylate (PAR).

The lower electrode may include one or more of aluminum (Al), gold (Au), silver (Ag), copper (Cu), platinum (Pt), tungsten (W), nickel (Ni), zinc (Zn), titanium (Ti), zirconium (Zr), hafnium (Hf), iridium (Ir), indium (In), gallium (Ga), molybdenum (Mo), TO (Tin oxide), ATO (Antimony doped Tin oxide), FTO (Fluorine doped Tin oxide), ITO (Indium Tin Oxide), FITO (Fluorinated Indium Tin oxide), IZO (Indium doped Zinc oxide), AZO (Al-doped ZnO), and ZnO (zinc oxide).

According to another embodiment of the present invention, there is provided a method of manufacturing a biodegradable memristor, which includes: forming a lower electrode on a substrate; forming a solid polymer electrolyte (SPE) layer on the substrate on which the lower electrode is formed; and forming a magnesium electrode on the SPE layer.

In the method, the biodegradable memristor may further include a conductive filament formed within the SPE layer through application of external bias.

In the method, the biodegradable memristor may have physically transient capability, wherein the physically transient capability may include forming a conductive filament within the SPE layer through application of an external bias, and selectively disconnecting the conductive filament by an external environment.

In the method, the SPE layer may include collagen.

In the method, specific details of the biodegradable memristor, the substrate, the lower electrode, the SPE layer, the magnesium electrode, and the like are the same as described above.

The SPE layer may be formed by preparing a collagen solution; mixing conductive particles into the collagen solution; and coating the collagen solution mixed with the conductive particles on a substrate on which the lower electrode is formed.

The SPE layer may be formed by one or more methods selected from spin coating, spray coating, bar coating, dip-coating, curtain coating, slot coating, roll coating, gravure coating, and vacuum thermal evaporation.

The magnesium electrode may be formed by a thermal evaporation method.

### BRIEF DESCRIPTION OF THE DRAWINGS

These and/or other aspects of the invention will become apparent and more readily appreciated from the following description of the embodiments, taken in conjunction with the accompanying drawings of which:

FIG. 1 is a diagram illustrating the structure of a biodegradable memristor according to an embodiment of the present invention;

FIG. 2 shows diagrams illustrating a process in which a biodegradable memristor according to an embodiment of the present invention exhibits physical transient capability;

FIG. 3 is a diagram illustrating transmission spectrum results obtained by using a UV-vis spectrometer for a solid polymer electrolyte layer formed on a PET substrate having ITO formed as a lower electrode according to an embodiment of the present invention;

FIG. 4 is a diagram illustrating results of checking bipolar RS behavior by sweeping a voltage between ±2.5 V at 10⁻³ A for a biodegradable memristor according to an embodiment of the present invention;

FIG. 5 is a diagram illustrating a scanning electron microscope (SEM) image of a cross-section of a biodegradable memristor according to an embodiment of the present invention;

FIG. 6 is a diagram illustrating results of examining data retention state for stability evaluation of a biodegradable memristor according to an embodiment of the present invention;

FIG. 7 is a diagram illustrating durability test results for 120 cycles at a read voltage of 0.2 V for reliability testing of a biodegradable memristor according to an embodiment of the present invention;

FIG. 8 is a diagram illustrating results of checking cumulative probability of current through switching variability of a biodegradable memristor according to an embodiment of the present invention;

FIG. 9 is a diagram illustrating results of checking double-logarithmic plots of I-V curves for each voltage region of positive and negative voltages to verify a conduction mechanism of a solid polymer electrolyte layer of a biodegradable memristor according to an embodiment of the present invention;

FIG. 10 is a diagram illustrating changes in I-V characteristics when a biodegradable memristor according to an embodiment of the present invention is bent under tensile and compressive stress with a bending radius of 5 mm;

FIG. 11 is a diagram illustrating bending-cycle measurement results up to a maximum of 1,000 cycles with a bending radius of 5 mm for a biodegradable memristor according to an embodiment of the present invention;

FIG. 12 is a diagram illustrating results of continuous voltage increase/decrease for each polarity of an applied voltage for a biodegradable memristor according to an embodiment of the present invention;

FIG. 13 is a diagram illustrating results of measuring current response over time based on continuous voltage sweeping for a biodegradable memristor according to an embodiment of the present invention; and

FIG. 14 is a diagram illustrating response results according to conductivity modulation by applying continuous AC pulses to verify long-term potentiation and long-term depression performance of a biodegradable memristor according to an embodiment of the present invention.

### DETAILED DESCRIPTION

Hereinafter, exemplary embodiments of the present invention will be described. However, the embodiments of the present invention may be modified into various other forms, and the technical spirit of the present invention is not limited to the embodiments described below. In addition, the embodiments of the present invention are provided to more fully explain the present invention to those having ordinary skill in the art.

The terminology used in this application is used solely for the purpose of describing specific examples. Therefore, for instance, singular expressions include plural expressions unless the context clearly indicates that only the singular form is intended. In addition, it should be noted that terms such as “comprise” or “include” used in this application are used to clearly indicate the presence of features, steps, functions, components, or combinations thereof described in the specification, and are not used to preliminarily exclude the presence of other features, steps, functions, components, or combinations thereof.

Meanwhile, unless otherwise defined, all terms used in this specification should be regarded as having the same meaning as commonly understood by those having ordinary skill in the art to which the present invention pertains. Therefore, unless clearly defined in this specification, specific terms should not be interpreted in an excessively idealized or formal sense. For example, singular expressions in this specification include plural expressions unless the context clearly indicates an exception.

In addition, terms such as “about” and “substantially” in this specification are used to mean at or close to the stated value when inherent manufacturing and material tolerances are presented.

Furthermore, expressions such as “on” and “upper” used in this specification mean being in contact with or formed on one surface or one side of a referenced object, and are not limited by a reference direction.

In the present invention, collagen, which is found in animal cell tissues, is used for a solid polymer electrolyte layer, and biodegradable magnesium is used for a memristor electrode, thereby providing a memristor with enhanced biocompatibility and biodegradability.

In addition, the present invention provides a memristor capable of implementing data-retention performance sufficient to operate as an electronic device while being compatible with physiological environments of the human body, in combination with biodegradability.

A physically transient electronic device (PiTED) according to the present invention has characteristics of being biologically dissolved without causing harm to the biological environment, and thus has high applicability in environmental protection and medical fields.

Hereinafter, a biodegradable memristor according to an embodiment of the present invention will be described in detail.

The biodegradable memristor according to an embodiment of the present invention may include a substrate, a lower electrode formed on the substrate, a solid polymer electrolyte (SPE) layer formed on the lower electrode, and a magnesium electrode formed on the SPE layer.

The biodegradable memristor according to an embodiment of the present invention has characteristics that enable use as a physically transient electronic device (PiTED) through the above described configuration. Specifically, the memristor according to an embodiment of the present invention may have physically transient capability.

Specifically, to be utilized as a PiTED, the ability to collect, retain, and store data is required. The memristor according to the present invention may control the collection, retention, and storage of electronic information by implementing a physically transient capability through the interaction of the lower electrode, the SPE layer, and the magnesium electrode. More specifically, the memristor according to the present invention may switch electrical resistance through formation or decomposition of conductive filaments within the SPE layer. Through this, the SPE layer formed between the lower electrode and the magnesium electrode may be imparted with as a capacitive function.

The physically transient capability of the biodegradable memristor will be described with reference to the drawings as follows.

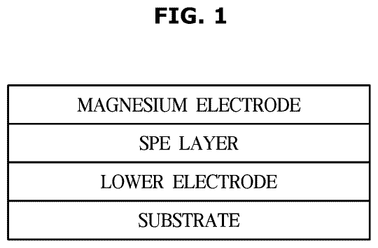

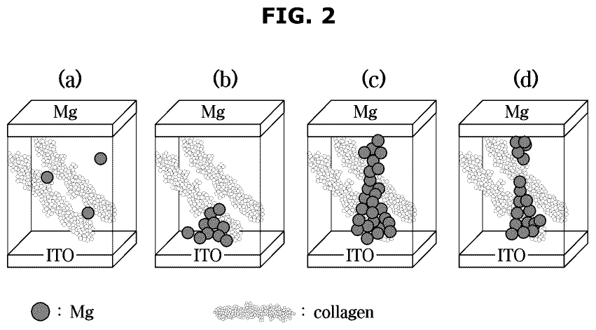

FIG. 1 is a diagram illustrating the structure of a biodegradable memristor according to an embodiment of the present invention, and FIG. 2 show diagrams illustrating a process in which a biodegradable memristor according to an embodiment of the present invention exhibits physical transient capability.

Referring to FIG. 1, the biodegradable memristor has a capacitor structure in which a solid polymer electrolyte (SPE) layer is sandwiched between ITO, which is a lower electrode, and an Mg electrode.

A process in which the biodegradable memristor exhibits physically transient capability is as follows. As shown in (a) of FIG. 2, when no external bias is applied, the biodegradable memristor maintains its original state. Subsequently, as shown in (b) of FIG. 2, when an appropriate positive bias is applied to the Mg electrode of the memristor, the electric field increases, and Mg atoms are oxidized to Mg²⁺ cations at an interface between the Mg electrode and the SPE layer. This is identical to anodic dissolution at an anode (a positive electrode) in an electrochemical metallization cell (Mg→Mg²⁺+2e⁻). The oxidized Mg²⁺ cations migrate toward the ITO lower electrode. Meanwhile, cathodic dissolution occurs at the lower electrode, and Mg²⁺ cations are reduced to Mg atoms at an interface between the SPE layer and the ITO lower electrode (Mg²⁺+2e⁻→Mg). In addition, as shown in (c) of FIG. 2, Mg atoms transiently self-assemble within the SPE layer to form conductive filaments. When the conductive filaments grow to generate a conductive path between the lower electrode and the Mg electrode, the memristor switches to an ON state. Meanwhile, as shown in (d) of FIG. 2, when a reverse polarity voltage that breaks the filaments is applied (Mg→Mg²⁺+2e⁻) to return the memristor to its original state, this may further migrates active Mg²⁺ cations (Mg²⁺+2e⁻→Mg) to disconnect the conductive filaments, thereby controlling the memristor to an OFF state.

In one example, the physically transient capability may include formation of conductive filaments within the SPE layer through application of an external bias, and selective disconnection of the conductive filaments by an external environment.

Through the formation of the conductive filaments, charges containing electronic information may be collected, retained, and stored. Subsequently, by decomposing the conductive filaments and controlling whether the conductive filaments are disconnected, the timing of collection, retention, and storage of the charges containing the electronic information may be adjusted.

The external bias may be varied as appropriate according to the type, amount, and the like of desired electronic information.

The disconnection of the conductive filaments may be performed through a method including one or more of application of a reverse polarity voltage, decomposition of the magnesium electrode, hydrolysis of the conductive filaments, and hydrolysis of the SPE layer.

A biodegradable memristor according to another embodiment of the present invention may be in a state further including a conductive filament formed within the SPE layer through application of an external bias.

The components used in the present invention will now be described.

First, the substrate on which the lower electrode is formed in the biodegradable memristor according to an embodiment of the present invention may serve to support the lower electrode. The substrate is not particularly limited as long as it is used as a substrate in conventional electronic devices, but may be for example, glass, silicon, poly(ethylene terephthalate) (PET), poly(ethylene naphthalate) (PEN), polyethersulfone (PES), polystyrene (PS), polycarbonate (PC), polyimide (PI), polydimethylsiloxane (PDMS), polyacrylate (PAR), and the like. In particular, to impart mechanically flexible properties to the biodegradable memristor of the present invention, it is preferable to use poly(ethylene terephthalate) (PET), poly(ethylene naphthalate) (PEN), polyethersulfone (PES), polystyrene (PS), polycarbonate (PC), polyimide (PI), polydimethylsiloxane (PDMS), polyacrylate (PAR), and the like. The transmittance of the substrate, specifically visible light transmittance, may be controlled. For example, the transmittance of visible light having a wavelength of 300 nm to 800 nm may be 20% to 90%, and the transmittance of visible light having a wavelength of 400 nm to 700 nm may be 85% to 90%. Within the above described range, the biodegradable memristor according to an embodiment of the present invention may implement transparency to further improve biocompatibility or usability in medical devices.

Next, the lower electrode formed on the substrate in the biodegradable memristor according to an embodiment of the present invention may include a conductive metal or a conductive oxide. For example, the conductive metal may be provided using aluminum (Al), gold (Au), silver (Ag), copper (Cu), platinum (Pt), tungsten (W), nickel (Ni), zinc (Zn), titanium (Ti), zirconium (Zr), hafnium (Hf), iridium (Ir), indium (In), gallium (Ga), molybdenum (Mo), or alloys thereof, and the conductive oxide may be provided using TO (Tin oxide), ATO (Antimony doped Tin oxide), FTO (Fluorine doped Tin oxide), ITO (Indium Tin Oxide), FITO (Fluorinated Indium Tin oxide), IZO (indium doped Zinc oxide), AZO (Al-doped ZnO), ZnO (zinc oxide), or the like.

Next, the SPE layer in the biodegradable memristor according to an embodiment of the present invention may include collagen, which has excellent compatibility with biological tissue and may be decomposed and dissolved in the body. The SPE layer may provide an environmentally friendly memristor with high biocompatibility.

The memristor according to the present invention includes a SPE layer formed of collagen, thereby being mechanically flexible and capable of bending and twisting, as well as being biocompatible and biodegradable. In such cases, the memristor according to the present invention may be applied to medical applications such as implantation into living bodies or direct use in biological neural networks.

In addition, the SPE layer includes collagen, and as needed, may further include one or more human-friendly natural proteins such as gelatin, silk fibroin, enzyme, sericin, lysozyme, amylose, amylopectin, albumen or the like.

Furthermore, the present invention may further include conductive particles to lower the operating voltage of the memristor and improve memristor characteristics.

The conductive particles may further enhance the transient capability of the memristor by moving electrons from the cathode to the anode during the formation or decomposition of conductive filaments within the SPE layer of the memristor, and may improve memristor characteristics by lowering the operating voltage of the memristor.

The conductive particles may include one or more selected from metals, metal oxides, metal nitrides, conductive polymers, and quantum dots, and preferably may include metal particles.

For example, the metal may include one or more selected from Mg, Ca, Sr, Ba, Au, Ag, Zn, Cu, In, Sn, Sb, Ni, Fe, and Pt; the metal oxide may include one or more selected from SiO₂, CaO, Cr₂O₃, MnO₂, TiO₂, ZrO₂, Y₂O₃, MgO, HfO₂, ZnO, Al₂O₃, SnO₂, ITO (indium tin oxide), and InZO (indium zinc oxide); and the metal nitride may include one or more selected from TiN, ZrN, NbN, CrN, VN, TaN, WN, AlN, GaN, InN, and Si₃N₄.

For example, the conductive polymer may include one or more selected from poly(methyl methacrylate) (PMMA), polyethylene (PE), polyethyleneimine (PEI), poly(3,4-ethylenedioxythiophene) (PEDOT), polytetrafluoroethylene (PTFE), polyvinylidene fluoride (PVDF), and poly(vinylphenol) (PVP).

In addition, for example, the quantum dots may include one or more selected from CdS quantum dots, ZnSe quantum dots, ZnS quantum dots, CdSe quantum dots, CdTe quantum dots, PbS quantum dots, PbSe quantum dots, InP quantum dots, GaAs quantum dots, GaN quantum dots, graphene quantum dots, CNT quantum dots, CH₃NH₃PbBr perovskite quantum dots, WS₂ quantum dots, MoS₂ quantum dots, CsPbCl₃ perovskite quantum dots, CuInS₂ quantum dots, Cu₂ZnSnS₄ quantum dots, CdTe/ZnTe quantum dots, Au/Al₂O₃ quantum dots, InP/GaAs quantum dots, CdTe/CdZnTe quantum dots, CdSe/CdS/ZnS quantum dots, and CdSe/ZnS quantum dots.

The average diameter of the conductive particles may be 0.1 nm to 100 nm, preferably 1 nm to 100 nm, more preferably 5 nm to 50 nm. Here, the average diameter refers to an equivalent circular diameter of particles detected by observing one cross-section of the active layer.

When the size of the conductive particles is larger than the thickness of the SPE layer, the surface of the SPE layer may not be uniform and memristor characteristics may not be exhibited; therefore, the average diameter of the conductive particles may be appropriately adjusted in consideration of the thickness of the SPE layer.

In the SPE layer, collagen and conductive particles may be included in a volume ratio of 1:0.001 to 1:1. Within this range, the physically transient capability of the biodegradable memristor according to the present invention may be further improved. In one example, collagen and conductive particles may be included in a volume ratio of 1:0.01 to 1:1 or 1:0.1 to 1:1. Within this range, the biodegradable memristor according to the present invention may be more advantageous for controlling the formation and disconnection of conductive filaments, thereby further improving physically transient capability.

The thickness of the SPE layer is not particularly limited as it may be appropriately adjusted in consideration of the thickness of the entire substrate and a desired degree of data retention through the physically transient capability to be implemented.

For example, the SPE layer may be formed on the lower electrode at a thickness of 10 nm to 500 nm, specifically 100 nm to 200 nm. Within this range, flexibility and stretchability of the biodegradable memristor of the present invention may be achieved while further improving physically transient capability.

The upper electrode formed on the SPE layer as described above may be a magnesium (Mg) electrode.

In the present invention, by forming a magnesium electrode as the upper electrode, a memristor with a biodegradable and flexible structure may be provided.

The thickness of the magnesium electrode is not particularly limited as it may be appropriately adjusted in consideration of the thickness of the entire substrate and a desired degree of data retention through the physically transient capability to be implemented.

For example, the magnesium electrode may be formed on the SPE layer at a thickness of 0.01 nm to 500 nm, specifically 0.1 nm to 500 nm, 1 nm to 500 nm, 10 nm to 500 nm, 10 nm to 200 nm, or 10 nm to 100 nm. Within this range, flexibility and stretchability of the biodegradable memristor according to the present invention may be achieved while further improving physically transient capability.

The shape of the magnesium electrode is not limited. As one example, the magnesium electrode may be applied on the SPE layer with a uniform or non-uniform thickness. As another example, the magnesium electrode may be coated as a plurality of figures (for example, circles, rectangles) having a certain area, arranged regularly or irregularly. As yet another example, the magnesium electrode may be formed in a pattern composed of lines or surfaces of a predetermined width.

Hereinafter, a method of manufacturing a biodegradable memristor according to an embodiment of the present invention will be described.

The method of manufacturing a biodegradable memristor according to the embodiment of the present invention may include: forming a lower electrode on a substrate; forming a solid polymer electrolyte (SPE) layer on the substrate on which the lower electrode is formed; and forming a magnesium electrode on the SPE layer.

First, a lower electrode is formed on the substrate.

Specifically, a film for forming the lower electrode may be formed on the substrate, a photoresist pattern may be formed, and patterning may be performed on the substrate using the photoresist pattern as a mask to form the lower electrode.

The lower electrode may be formed by one or more methods selected from sputtering, atomic layer deposition (ALD), pulsed laser deposition (PLD), thermal evaporation, electron-beam evaporation, physical vapor deposition (PVD), molecular beam epitaxy (MBE), chemical vapor deposition (CVD), and solution processing methods, but it is not limited thereto.

When the thickness of the lower electrode is excessively thick or excessively thin, the flexibility and stretchability of the memristor may be lowered, and the inherent function of the lower electrode may be degraded. Therefore, the lower electrode may be formed on the substrate at a thickness of about 200 nm.

Before forming the SPE layer on the lower electrode, the substrate on which the lower electrode is formed may further undergo cleaning by sequential ultrasonic treatment in acetone, isopropanol, and distilled water for 20 to 40 minutes each, followed by surface modification through UV ozone treatment.

Subsequently, the SPE layer is formed on the cleaned lower electrode.

The SPE layer may include collagen. As needed, the SPE layer may further include one or more human-friendly natural proteins such as gelatin, silk fibroin, enzyme, sericin, lysozyme, amylose, amylopectin, albumen, or the like.

In addition, the SPE layer may further include conductive particles to further enhance the transient capability of the memristor by allowing electrons to move from the cathode to the anode during formation or decomposition of conductive filaments within the SPE layer.

The SPE layer may be formed by preparing a collagen solution by mixing distilled water with collagen powder; incorporating conductive particles into the collagen solution as needed; and coating or depositing the collagen solution containing the conductive particles onto the lower electrode.

The coating may be performed by spin coating, spray coating, bar coating, dip-coating, curtain coating, slot coating, roll coating, gravure coating, or the like, and the deposition may be performed by vacuum thermal evaporation, but it is not limited thereto.

The SPE layer may be formed on the lower electrode at a thickness of 10 nm to 500 nm, specifically 100 nm to 200 nm. Within this range, the flexibility and stretchability of the biodegradable memristor according to the present invention may be achieved while further improving the physically transient capability.

After the SPE layer is formed, annealing may be performed at 50 to 80° C., specifically at 60° C., to remove residual solvent remaining in the SPE layer.

Next, a magnesium electrode, which is the upper electrode, is formed on the SPE layer.

In the present invention, by forming a biodegradable magnesium electrode on a highly biocompatible and bio-dissolvable SPE layer, the biodegradability of the memristor according to the present invention may be further improved.

The magnesium electrode may be formed by the same method as the lower electrode described above or by a different method, and the direction of the magnesium electrode may be formed in a direction crossing the direction of the lower electrode.

The magnesium electrode may be formed on the SPE layer at a thickness of 0.01 nm to 500 nm, specifically 0.1 nm to 500 nm, 1 nm to 500 nm, 10 nm to 500 nm, 10 nm to 200 nm, or 10 nm to 100 nm. Within this range, the flexibility and stretchability of the biodegradable memristor according to the present invention may be achieved while further improving the physically transient capability.

In the method of manufacturing a biodegradable memristor according to the embodiment of the present invention, specific details of the biodegradable memristor, the substrate, the lower electrode, the SPE layer, the magnesium electrode, and the like are the same as those described above in this specification.

The biodegradable memristor according to the present invention as described above uses a collagen electrolyte and a magnesium electrode, which are biocompatible and bio-dissolvable, and is therefore suitable for application in biological environments, being decomposable and dissolvable in the human body, and thus being applicable as an environmentally friendly electronic device with high biocompatibility.

Hereinafter, the present invention will be described in more detail through following examples. However, the following examples are only for illustrating the present invention, and the scope of the present invention is not limited thereto.

### Embodiment 1. Manufacturing of Biodegradable Memristor

In this embodiment, a biodegradable memristor was fabricated using poly(ethylene terephthalate) (PET) as the substrate, indium tin oxide (ITO) as the lower electrode, collagen powder extracted from fish scales as collagen, and magnesium (Mg) as the upper electrode.

First, 4 wt % collagen powder extracted from fish scales was dissolved in distilled water and then stirred at room temperature for 1 hour to prepare a collagen solution.

In addition, the PET substrate with ITO was cleaned by ultrasonic treatment in acetone, isopropanol, and distilled water for 30 minutes each, and then surface-modified by UV ozone treatment.

The prepared collagen solution was spin-coated on the surface-modified PET substrate at 500 rpm for 5 seconds and 1200 rpm for 40 seconds, then dried overnight at room temperature and annealed at 60° C. in a vacuum oven to form a SPE layer having a thickness of about 100 nm.

Subsequently, a magnesium electrode with a diameter of 100 μm was patterned on the PET substrate, on which the SPE layer was formed, through thermal evaporation using a shadow mask to manufacture the biodegradable memristor.

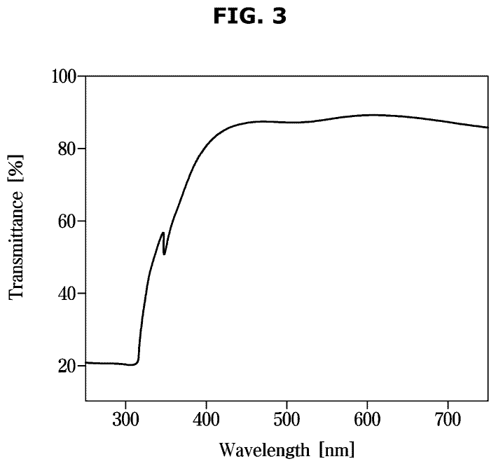

The transmission spectrum of the SPE layer formed on the PET substrate having ITO was measured using a UV-vis spectrometer. As shown in FIG. 3, it exhibited a transmittance of 86% at a wavelength of 450 nm, and a high transmittance of 85-90% in most of the visible region.

### Embodiment 2. Electrical Characteristics Analysis

To evaluate the electrical characteristics of the biodegradable memristor manufactured in Embodiment 1, current-voltage (I-V) characteristics were analyzed as follows.

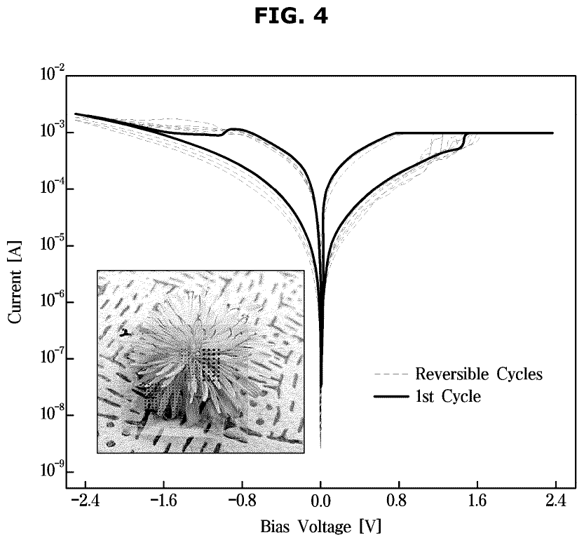

Bipolar resistive switching (RS) behavior was checked by a sweeping voltage between ±2.5V at a compliance current of 10⁻³ A. As shown in FIG. 4, the biodegradable memristor manufactured in Embodiment 1 exhibited forming-free bipolar RS behavior under DC sweeping bias, switched to an ON state at a set voltage (Vₛₑₜ) of about 1.44 V, under positive voltage bias, transitioned from a high resistance state (HRS) to a low resistance state (LRS), and transited from LRS to HRS under negative voltage bias.

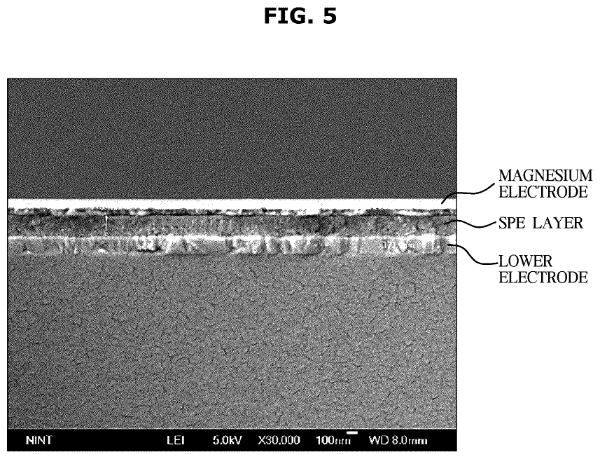

In addition, a cross-sectional scanning electron microscope (SEM) image of the biodegradable memristor manufactured in Embodiment 1 was shown in FIG. 5, and it was confirmed that a dense and uniform SPE layer was successfully manufactured in the sandwich structure of the biodegradable memristor.

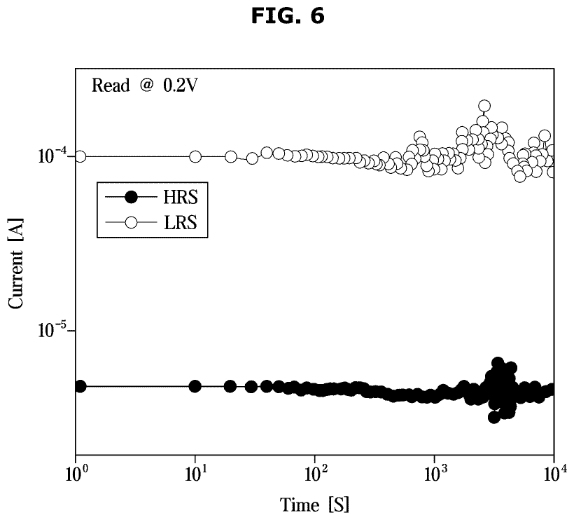

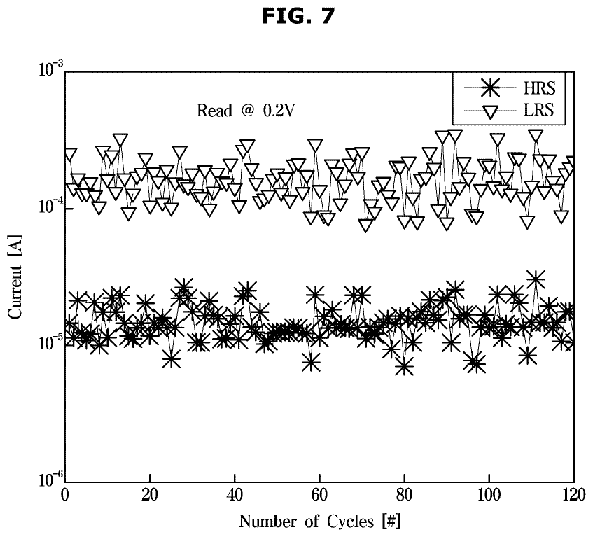

In addition, in order to evaluate the stability of the memristor, data retention was examined with a reading bias of 0.2V under ambient conditions. As shown in FIG. 6, an on/off ratio of about 20 was obtained for 10⁴ seconds without performance degradation. In order to test the reliability of the biodegradable memristor, an endurance test was performed for 120 cycles at a reading voltage of 0.2V and the results were shown in FIG. 7. Based on the data retention state and endurance test results of the biodegradable memristor manufactured in Embodiment 1, as shown in FIGS. 6 and 7, it was confirmed that the biodegradable memristor according to the present invention are reliable, and exhibit stable RS characteristics.

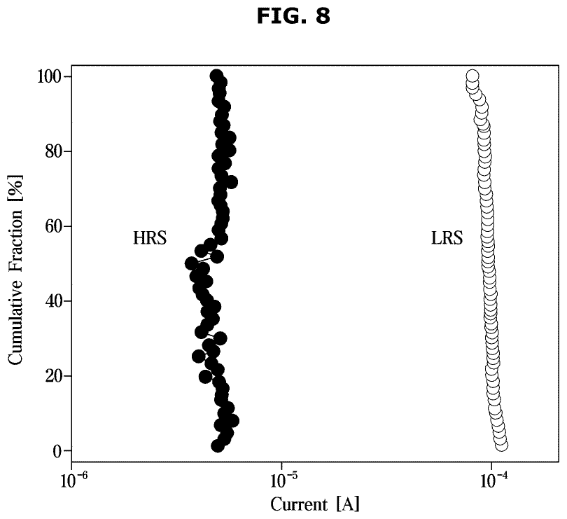

In addition, the cumulative probability of the current was checked through the switching variability of the biodegradable memristor manufactured in Embodiment 1. As shown in FIG. 8, it was confirmed that the average set and reset currents for all switching cycles were stable.

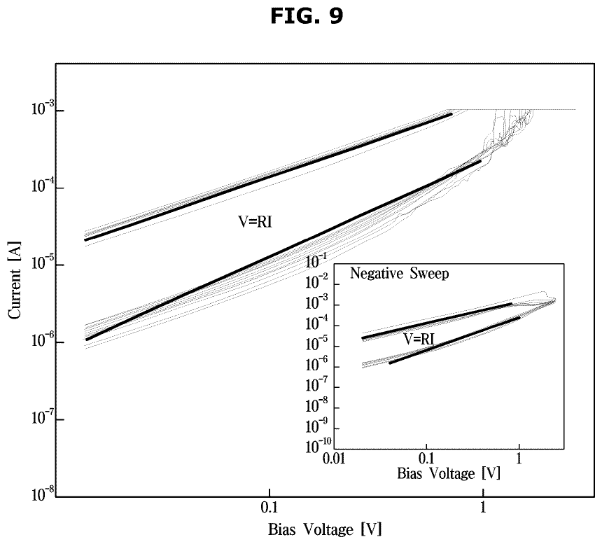

Meanwhile, in order to clarify the conduction mechanism in the SPE layer of the biodegradable memristor manufactured in Embodiment 1, double-logarithmic plots of I-V curves for both positive and negative voltage regions were further examined and shown in FIG. 9. FIG. 9 shows the ON/OFF states in a double logarithmic plot using an Ohmic model, in which the linear fitting for both the LRS and HRS states indicates Ohmic conduction mechanism and filament current conduction. As shown in FIG. 9, the I-V curves showed linear behavior in both the 0V→2.4V and −2.4V→0V regions, which are ON/OFF states, confirming consistency with Ohmic conduction.

From the results of the electrical characteristics analysis of the biodegradable memristor manufactured in Embodiment 1, it was confirmed that the memristor according to the present invention is a reliable biodegradable memristor.

### Embodiment 3. Mechanical Stability Analysis

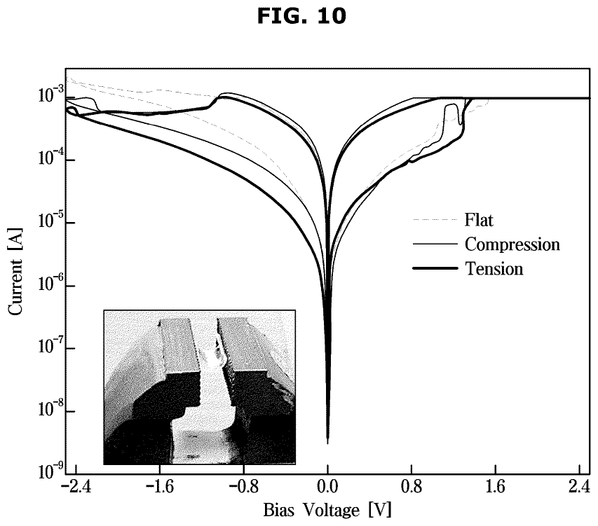

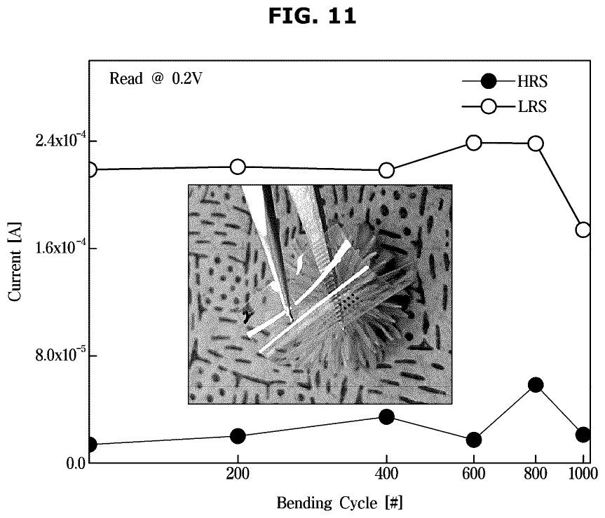

In order to evaluate the mechanical flexibility of the biodegradable memristor manufactured in Embodiment 1, the memristor was bent under tensile and compressive stress with a curvature radius of 5 mm, and as shown in FIG. 10, it was confirmed that the I-V characteristics of the memristor subjected to compressive and tensile bending were not significantly lowered. In addition, the bending cycle measurement test whose results are shown in FIG. 11 was performed up to a maximum of 1000 cycles with a curvature radius of 5 mm, and the results confirmed that the biodegradable memristor manufactured in Embodiment 1 maintained stability without deformation even under mechanical stress.

Through these results, it was confirmed that the biodegradable memristor according to the present invention has reliable memristor characteristics as a fabricated device, such as data retention, durability, and uniformity suitable for operating as a flexible biomemristor.

### Embodiment 4. Synaptic Characteristics Analysis

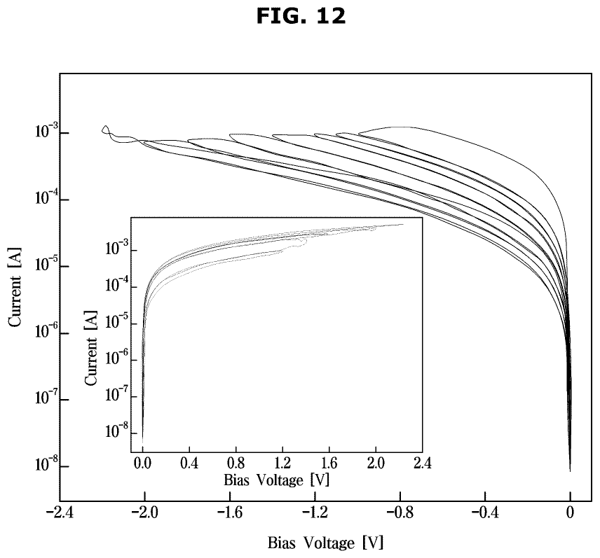

In order to analyze the synaptic characteristics of the biodegradable memristor manufactured in Embodiment 1, synaptic characteristics were analyzed by applying repetitive positive and negative voltage sweeps to the biodegradable memristor of Embodiment 1. As shown in FIG. 12, it was confirmed that the biodegradable memristor manufactured in Embodiment 1 exhibited gradual increase/decrease in current response according to voltage potentiation/depression of repetitively applied voltage, similar to the potentiation/depression of biological synapses in the increase/decrease current of the I-V curve.

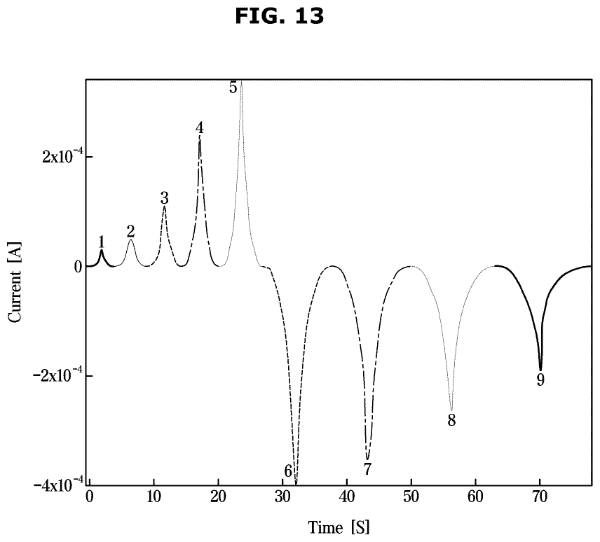

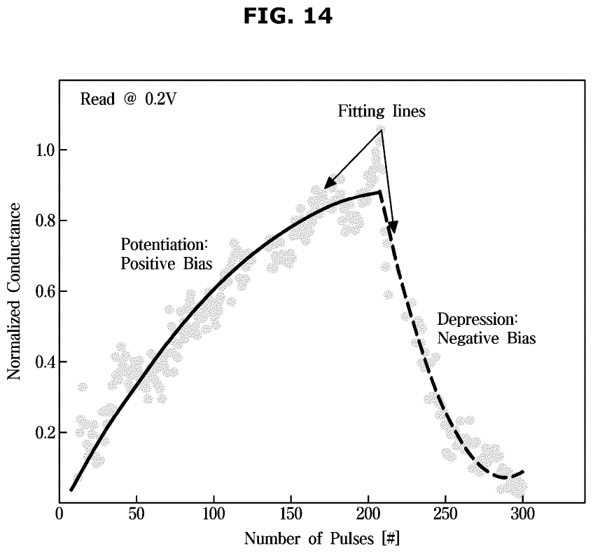

In addition, time-dependent current responses were measured based on the applied continuous voltage sweeps, and the results of current response to various stimuli were shown in FIG. 13. Additionally, in order to confirm long-term potentiation and long-term depression performance, continuous AC pulses were applied, and as shown in FIG. 14, continuous identical positive pulses (2V) were applied to increase the conductivity, and then continuous negative pulses (−2V) were applied to decrease the conductivity. A read pulse (0.2V) was applied after each stimulation sequence. As shown in FIGS. 13 and 14, it was confirmed that the conductivity of the biodegradable memristor was stably modulated by continuous pulses.

As is apparent from the above, according to the present invention, a biomemristor that is harmless in an in-vivo environment, has characteristics of dissolving and degrading inside the human body, and is mechanically flexible to be usable as a bio-electronic device in various fields, and a method of manufacturing the same can be provided.

The effects of the present invention are not limited to those described above, and other effects that are not described above will be clearly understood by those skilled in the art from the above detailed description.

While exemplary embodiments of the present invention have been illustrated and described above, the invention is not limited to the specific embodiments disclosed herein. Various modifications and changes may be made by those skilled in the art without departing from the spirit and scope of the invention as defined in the appended claims.

What is claimed is:

1. A biodegradable memristor comprising:
a substrate;
a lower electrode formed on the substrate;
a solid polymer electrolyte (SPE) layer formed on the lower electrode; and
a magnesium electrode formed on the SPE layer.

2. The biodegradable memristor of claim 1, further comprising a conductive filament formed within the SPE layer through application of an external bias.

3. The biodegradable memristor of claim 1, wherein the biodegradable memristor has physically transient capability.

4. The biodegradable memristor of claim 3, wherein the physically transient capability includes forming a conductive filament within the SPE layer through application of an external bias, and selectively disconnecting the conductive filament by an external environment.

5. The biodegradable memristor of claim 4, wherein the disconnecting of the conductive filaments is performed through a method including one or more of application of a reverse polarity voltage, decomposition of the magnesium electrode, hydrolysis of the conductive filament, and hydrolysis of the SPE layer.

6. The biodegradable memristor of claim 1, wherein the SPE layer comprises collagen.

7. The biodegradable memristor of claim 1, wherein the SPE layer comprises collagen and further comprises one or more selected from gelatin, silk fibroin, enzyme, sericin, lysozyme, amylose, amylopectin, and albumen.

8. The biodegradable memristor of claim 1, wherein the SPE layer further comprises conductive particles.

9. The biodegradable memristor of claim 8, wherein the conductive particles comprise one or more selected from metals, metal oxides, metal nitrides, conductive polymers, and quantum dots.

10. The biodegradable memristor of claim 1, wherein the substrate comprises one or more of glass, silicon, poly(ethylene terephthalate) (PET), poly(ethylene naphthalate) (PEN), polyethersulfone (PES), polystyrene (PS), polycarbonate (PC), polyimide (PI), polydimethylsiloxane (PDMS), and polyacrylate (PAR).

11. The biodegradable memristor of claim 1, wherein the lower electrode comprises one or more of aluminum (Al), gold (Au), silver (Ag), copper (Cu), platinum (Pt), tungsten (W), nickel (Ni), zinc (Zn), titanium (Ti), zirconium (Zr), hafnium (Hf), iridium (Ir), indium (In), gallium (Ga), molybdenum (Mo), TO (Tin oxide), ATO (Antimony doped Tin oxide), FTO (Fluorine doped Tin oxide), ITO (Indium Tin Oxide), FITO (Fluorinated Indium Tin oxide), IZO (Indium doped Zinc oxide), AZO (Al-doped ZnO), and ZnO (zinc oxide).

12. A method of manufacturing a biodegradable memristor, the method comprising:
forming a lower electrode on a substrate;
forming a solid polymer electrolyte (SPE) layer on the substrate on which the lower electrode is formed; and
forming a magnesium electrode on the SPE layer.

13. The method of claim 12, wherein the biodegradable memristor further comprises a conductive filament formed within the SPE layer through application of external bias.

14. The method of claim 12, wherein the biodegradable memristor has physically transient capability,
wherein the physically transient capability includes forming a conductive filament within the SPE layer through application of an external bias, and selectively disconnecting the conductive filament by an external environment.

15. The method of claim 12, wherein the SPE layer comprises collagen.
